(19) United States
(12) Patent Application Publication
(10) Pub. No.: US 2011/0248869 A1
(43) Pub. Date: Oct. 13, 2011

(54) Miniature 4-key one-hand alphanumeric keyboard

(76) Inventor: Martin Miller, West Kelowna (CA)

(21) Appl. No.: 12/757,036

(22) Filed: Apr. 8, 2010

(51) Int. Cl. H03M 11/00

(52) U.S. Cl. 341/22

(57) ABSTRACT

A miniature alpha-numeric keyboard, operated by one hand, for use with computers, cell phones and mobile electronic devices. The device has only 4 keys, one dedicated to each of the four fingers, and a thumb receptacle or pouch, arranged in such a way that when the thumb is inserted in the pouch, the four fingers rest naturally on the four keys. While the keyboard is being operated, the thumb inserted in the receptacle supports the keyboard in position, each of the four fingers resting above its own key, preventing it from moving out of place. Support against the fingers depressing the keys is provided by resting the device against another object—a table, an armrest, the operator's own body or pocket—or any other object that a hand would normally rest on. Alphanumeric, control and special characters are generated by pressing the four keys using composite keystrokes, as described in U.S. Pat. No. 6,952,173.

### CROSS-REFERENCE TO RELATED APPLICATIONS

Not Applicable

### FIELD OF THE INVENTION

This invention relates to an apparatus for providing alphanumeric input to computers and other electronic devices by means of operating four keys by four fingers of one hand.

### BACKGROUND OF THE INVENTION

A number of attempts to design a portable keyboard operated by one hand have been described in the prior art, but none of these seem to have been very successful. The reason is that the fingers and the thumb of one hand cannot really be used to hold AND to operate the keyboard at the same time.

To resolve this issue the keyboard must be held or attached to the hand (or to another part of the body) by some sort of harness, frame or some other attachment device. For example, see U.S. Pat. No. 6,429,854.

The problem with these attempts is that they make the keyboard large, awkward to use and cumbersome to operate, defeating the purpose of a truly portable device.

The present invention solves this problem by clearly separating the functions of operating the keys and holding the device, which is further separated into holding the device in place, and providing support against the keys being pressed:
a) the four fingers are dedicated to operating the four keys
b) the thumb is dedicated to holding the keyboard in position, so that the keys are always under the fingertips
c) additional support against the movement of the keys being pressed is provided by resting the hand and the device against another object, like the operator's body

This approach allows the present invention to be made of only two small parts: a base with a row of four keys, and a thumb receptacle attached to the base on one side (on the left for a right-handed keyboard; on the right side of the base of a left-handed keyboard).

### BRIEF SUMMARY OF THE INVENTION

The invention describes a device for generating alphanumeric characters as input to electronic devices—a miniature computer keyboard with only four keys operated by one hand.

The keyboard has two parts. The first part is a small base with four keys arranged in a row, one for each of the four fingers. The second part is an adjustable pouch or receptacle large enough to fit the thumb of the hand operating the keyboard. The two parts are attached in such a way that when the thumb is inserted in the pouch, the four fingers of the hand fall comfortably on the four keys, with the hand in a natural, relaxed position.

While the keyboard is being operated, the thumb is inserted in the receptacle and holds the keyboard in position, with the four fingers resting each on its own key, preventing the keyboard from moving out of place. Support against the fingers pressing the keys is provided by resting the device against another object, like a table, an armrest, the operator's own body or pocket, or any other suitable object.

The keyboard could be connected to the electronic device receiving the input by a cable (such as USB cable). However in the preferred embodiment the connection would be via Bluetooth or other wireless means, providing much greater flexibility and ease of use, especially with mobile devices.

All the alphanumeric, control and special characters are generated by pressing the four keys using composite keystrokes, as described in U.S. Pat. No. 6,952,173.

### BRIEF DESCRIPTION OF THE SEVERAL VIEWS OF THE DRAWING

Not Applicable

### DETAILED DESCRIPTION OF THE INVENTION

The preferred embodiment of the invention has two parts:
1. A small base with only four keys. The keys are arranged in a row. They are of a similar type and size as keys on a notebook computer keyboard. The base for the keys is thick enough only to hold the required electronics and big enough only to hold the four keys, plus a small protrusion on either the left or the right side to support attachment of the second part.
2. A thumb receptacle or a pouch of such a size and shape that when the thumb is inserted, it should fit snugly, holding in firmly but comfortably. The size and to a certain extent the shape of the pouch may be adjustable by using Velcro straps or in a similar way, so that the receptacle may perfectly fit thumbs of different proportions.

The thumb receptacle is attached to one side of the key base—to the left side of a right-hand keyboard, to the right side in case of a left-hand keyboard. The thumb receptacle and the base with the four keys are arranged in an approximately right angle (or slightly less), so that when the thumb is inserted in the receptacle the tips of the four fingers are positioned above the four keys, while the hand is held in a natural, relaxed position. The two parts may be joined permanently or using an adjustable joint, which would help adjusting the position of the keys in relation to the thumb for hands of different sizes.

The joint may also allow adjusting the angle between the thumb receptacle and the key base to such a degree so as to allow turning the key base all the way (180 degrees) to the other side—thus making the same device usable by either right or left hand.

While the keyboard is being operated, the thumb inserted in the receptacle holds the keyboard in position, the four fingers resting each on its own key, preventing the keyboard from moving sideways. Support against the fingers depressing the keys is provided by resting the device against another object—the operator's own body or pocket, table, armrest of a chair—anything that the hand can normally rest on.

Each of the four fingers has its own dedicated key. The fingers only need to depress and release the keys; there is never any need to move them away or from key to key.

Although the fact that another object is required to support the keyboard while it is used may seem as a disadvantage at first, in reality it is not. Even when standing or walking, it is more comfortable to operate a one-handed keyboard while the hand is resting against the side of one's body or in his/her pocket. On the other hand, the fact that the keyboard is attached to the hand solely by inserting the thumb and no other ‘harnesses’, gloves or other awkward attachment devices are required permits the extreme miniaturization of the keyboard, making it ideal for portable devices and wearable computing. Plus it makes it that much easier to operate: just slip it on your thumb, do the typing and slip it off. And you can do that without taking your hand out of your pocket.

The four keys are used to generate all the alphanumeric characters plus any required control and special characters by utilizing the so called composite keystrokes, as described in U.S. Pat. No. 6,952,173.

What is claimed is:

1. An apparatus used for generating characters as input to electronic devices comprising a small base with four (4) keys and a thumb receptacle. The said keys and the said receptacle are arranged in such a way that when a thumb is inserted into the said receptacle the four fingers rest naturally on the said four keys, each finger having one dedicated key.

2. An apparatus as described in claim 1. where, when the keyboard is in use, the thumb inserted in the receptacle keeps the keys in place, aligned with the fingertips, while the keyboard is supported against the movement of depressing the keys by resting the device against another object (for example a table, an armrest, the operator's own body or pocket, etc.).

3. An apparatus as described in claim 1. where the receptacle part of the apparatus is attached to the part with the four keys by means of an adjustable joint, allowing adjustment of the angle between the thumb and the keyboard, so that with the thumb inserted the fingers can operate the four keys comfortably when used by hands of different sizes.

4. An apparatus as described in claim 3. where the joint connecting the thumb receptacle and the keyboard allows changing the angle by more than 180 degrees, thereby allowing adjusting the same device for use by either a left or right hand.

5. An apparatus as described in claim 1. where the size and to certain extent the shape of the thumb receptacle is adjustable, using overlapping Velcro straps or other similar means, to snugly fit thumbs of varying sizes.

6. An apparatus as described in claim 1. where the apparatus communicates with the electronic device via Bluetooth or other wireless means.

7. An apparatus as described in claim 1. where the characters are generated using the so called composite keystrokes as described in U.S. Pat. No. 6,952,173.
